(19) United States
(12) Patent Application Publication
(10) Pub. No.: US 2004/0108583 A1
(43) Pub. Date: Jun. 10, 2004

(54) Thin scale outline package stack

(76) Inventors: Glen E. Roeters, Huntington Beach, CA (US); John Patrick Sprint, Huntington Beach, CA (US); Joel Andrew Mearig, Huntington Beach, CA (US)

Correspondence Address: Kit M. Stetina, STETINA BRUNDA GARRED & BRUCKER, Suite 250, 75 Enterprise, Aliso Viejo, CA, 92656, US

(21) Appl. No.: 10/310,368

(22) Filed: Dec. 5, 2002

(51) Int. Cl. H01L 23/02

(52) U.S. Cl. 257/686

(57) ABSTRACT

A semiconductor die stack is provided which includes at least two semiconductor dies each having electrical leads. The leads of the upper semiconductor die are directly electrically connected to respective leads of the lower semiconductor die. Electrical connectivity is maintained throughout the semiconductor die stack. The electrical connection between respective leads of the upper and lower semiconductor die is made outside the footprint of the semiconductor die.

### CROSS-REFERENCE TO RELATED APPLICATIONS

### (Not Applicable) STATEMENT RE: FEDERALLY SPONSORED RESEARCH/DEVELOPMENT

### (Not Applicable)

### BACKGROUND OF THE INVENTION

The present invention relates generally to semiconductor die stacks, and more particularly to semiconductor die stacks having electrical connections routed vertically and horizontally between each semiconductor die in the semiconductor die stack. In this regard, multiple integrated circuit chips such as non-packaged or packaged semiconductor dies may be quickly, easily and inexpensively vertically interconnected in a volumetrically efficient manner.

Multiple techniques are currently employed in the prior art to increase memory capacity on a printed circuit board. Such techniques include the use of larger memory chips, if available, and increasing the size of the circuit board for purposes of allowing the same to accommodate more memory devices or chips. In another technique, vertical plug-in boards are used to increase the height of the circuit board to allow the same to accommodate additional memory devices or chips.

Perhaps one of the most commonly used techniques to increase memory capacity is the stacking of memory devices into a vertical chip stack, sometimes referred to as 3D packaging or Z-Stacking. In the Z-Stacking process, from two (2) to as many as eight (8) memory devices or other integrated circuit (IC) chips are interconnected in a single component (i.e., chip stack) which is mountable to the “footprint” typically used for a single package device such as a packaged chip. The Z-Stacking process has been found to be volumetrically efficient, with packaged chips in TSOP (thin small outline package) or LCC (leadless chip carrier) form generally being considered to be the easiest to use in relation thereto. Though bare dies or chips may also be used in the Z-Stacking process, such use tends to make the stacking process more complex and not well suited to automation.

In the Z-Stacking process, the IC chips or packaged chips must, in addition to being formed into a stack, be electrically interconnected to each other in a desired manner. There is known in the prior art various different arrangements and techniques for electrically interconnecting the IC chips or packaged chips within a stack. Examples of such arrangements and techniques are disclosed in U.S. Pat. No. 4,956,694 entitled INTEGRATED CIRCUIT CHIP STACKING issued Sep. 11, 1990, U.S. Pat. No. 5,612,570 entitled CHIP STACK AND METHOD OF MAKING SAME issued Mar. 18, 1997, and U.S. Pat. No. 5,869,353 entitled MODULAR PANEL STACKING PROCESS issued Feb. 9, 1999. All of which are assigned to the subject Assignee, the disclosures of which are expressly incorporated herein by reference.

The various arrangements and techniques described in these above referenced issued patents have been found to provide semiconductor die stacks which are relatively easy and inexpensive to manufacture, and are well suited for use in a multitude of differing applications. The present invention provides yet an additional arrangement and technique for forming a volumetrically efficient semiconductor die stack. In the semiconductor die stack of the present invention, connections are routed from the bottom of the semiconductor die stack to the perimeter thereof so that interconnections can be made vertically which allows non-packaged or packaged semiconductor dies to be stacked in a manner providing the potential for significant increases in the production rate of the semiconductor die stack and resultant reductions in the cost thereof.

### BRIEF SUMMARY OF THE INVENTION

In an embodiment of the present invention, a semiconductor die stack is provided which includes at least two semiconductor dies. The semiconductor dies are vertically stacked upon each other. Each semiconductor die has electrical leads. The leads of the upper semiconductor die are directly connected to respective leads of the lower semiconductor die.

Each semiconductor die defines opposed top and bottom surfaces and four side surfaces. The leads of each semiconductor die extend parallel to the opposed top and bottom surfaces from at least one of the side surfaces. The leads of the top semiconductor die are formed downwardly.

As a preliminary matter, the distance from the side surface from which the lead extends out from to the outside radius of the bend of the lead of each semiconductor die defines a bend distance. The bend distance of the leads of each upper semiconductor die is progressively larger. The bend distance of the leads of the upper semiconductor die is greater than the bend distance of the leads of the lower semiconductor die by the thickness of the leads.

The electrical connections between respective leads of the upper and lower semiconductor dies are made with conductive ink or conductive paste. Alternatively, the electrical connections between respective leads of the upper and lower semiconductor dies are made through laser welding or arc welding.

A thermally conductive and electrically isolated adhesive preform may further be disposed between each upper and lower semiconductor die. This adhesive preform may consist of electrical conductors to jumpers to selected leads of the semiconductor die. Alternatively external metal jumpers can be utilized.

### BRIEF DESCRIPTION OF THE DRAWINGS

These, as well as other features of the present invention, will become more apparent upon reference to the drawings wherein:

FIG. 1 is an exploded orthographic view of two semiconductor dies vertically stacked upon each other;

FIG. 2 is a cross sectional view of the stacked semiconductor dies of FIG. 1; and

FIG. 3 is a cross sectional view of three vertically stacked semiconductor dies.

### DETAILED DESCRIPTION OF THE INVENTION

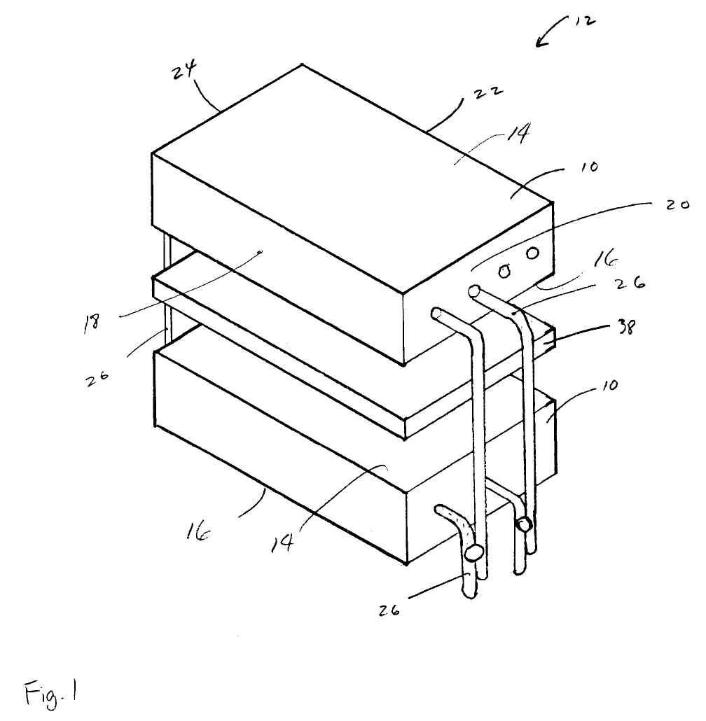

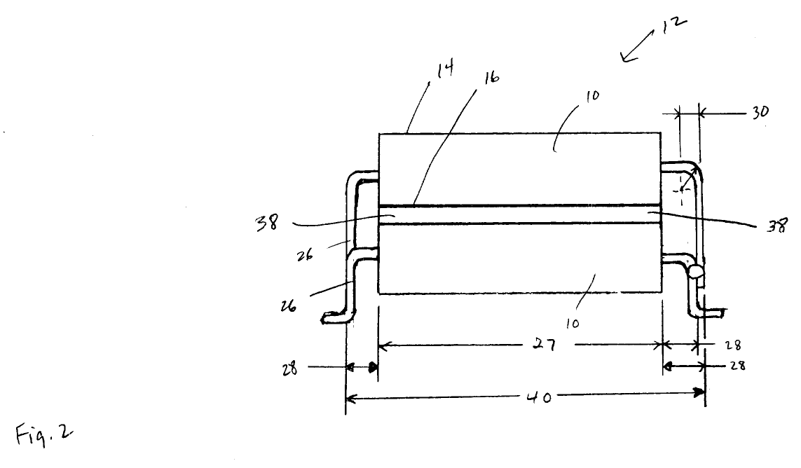

A generic semiconductor die 10 is used to describe the various features of the present invention, as shown in the FIGS. 1-3. By way of example and not limitation, the semiconductor die 10 may be a thinned and background bare die, a chip scale package (CSP) device, and/or a thin scale outline package (TSOP) (as specifically illustrated in FIG. 2). In this regard, alternative embodiments of the present invention are not limited by the type of semiconductor die 10 or semiconductor die package within the scope and spirit of the present invention.

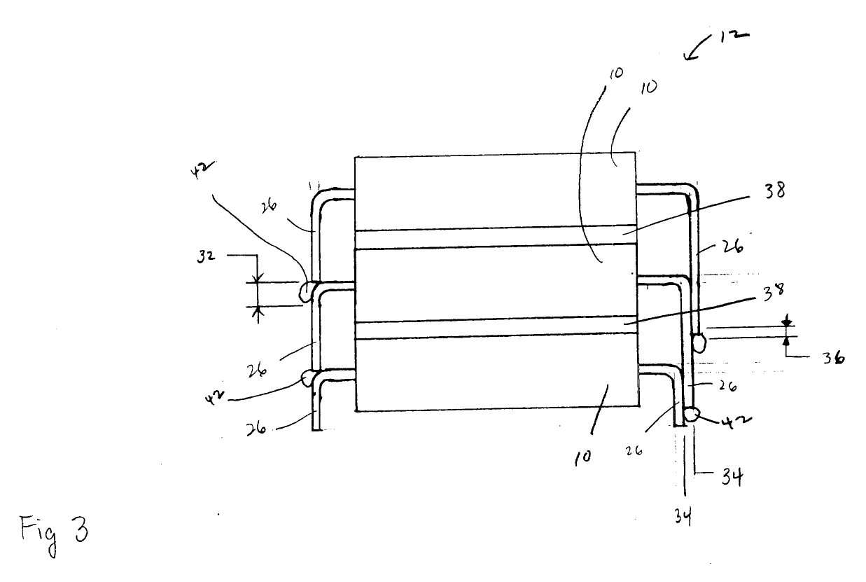

Referring now to the drawings wherein the drawings are used to illustrate preferred embodiments of the present invention and not for limiting the same, FIGS. 1 and 3 depict a semiconductor die stack 12 including two and three semiconductor dies 10 respectively, vertically stacked upon each other and electrically connected to each other. In this regard, the present invention is not limited by the number of semiconductor dies 10 to be stacked upon each other. In other words, two or more semiconductor dies 10 may be vertically stacked upon each other yet maintain the electrical connectivity between the stacked semiconductor dies 10.

In an embodiment of the present invention depicted in FIGS. 1 and 2, a semiconductor die stack 12 is provided which includes at least two semiconductor dies 10. The semiconductor dies 10 are vertically stacked and electrically connected to each other.

Specifically, in relation to the semiconductor dies 10, each semiconductor die 10 defines opposed top and bottom surfaces 14, 16. Additionally, each semiconductor die 10 defines four side surfaces 18, 20, 22, 24, as shown in FIG. 1. Each semiconductor die 10 has electrical leads 26 which are electrically connected to a die circuit of the semiconductor die 10. In this regard, the leads 26 are the input/output of the die circuit of the semiconductor die 10.

In relation to the leads 26, the leads 26 extend out from at least one of the four side surfaces 18, 20, 22, 24 of the semiconductor die 10. Preferably, the leads 26 extend out from at least two or four opposing side surfaces 18, 20, 22, 24. In this regard, generally, the residual stresses within the stacked semiconductor dies 10 will be more uniform compared to stacked semiconductor dies 10 wherein the leads 26 extend out from adjacent side surfaces (i.e., non-opposing side surfaces; e.g., 18 and 20, or 22 and 24) of the semiconductor die 10.

The leads 26 extend out from the side surface(s) 18, 20, 22, 24. Preferably, the leads 26 extend out such that they are parallel to the opposed top and bottom surfaces 14, 16, as shown in FIG. 2. In other words, the leads 26 extend out from the side surface 18, 20, 22, 24 such that the leads 26 are substantially perpendicular to the side surface 18, 20, 22, 24. The leads 26 are substantially perpendicular to the side surface 18, 20, 22, 24 as long as the electrical connection between semiconductor dies 10 may be made outside of the footprint 27 of the stacked semiconductor dies 10.

The leads 26 of the top semiconductor die 10 are formed downward such that the leads 26 may be electrically connected to an overall electrical circuit. The forming of the leads 26 define a bend distance 28. The bend distance 28 is equal to the perpendicular distance from the side surface 18, 20, 22, 24 from which a lead 26 extends to the furthest distance of the bend radius 30, as shown in FIG. 2. In this regard, the leads 26 are generally not modified when the semiconductor die 10 is a TSOP. In general, the leads 26 are conductive and malleable.

The leads 26 of the upper semiconductor die(s) 10 are bent downward so as to be able to physically and electrical connect with respective ones of the leads 26 of the lower semiconductor die 10. In general, the bend distance 28 of the upper semiconductor die(s) 10 may be slightly greater than or equal to the bend distance 28 of the lower semiconductor die 10, as shown in FIG. 3. In particular, the right side of the stack 12 depicts the bend distance 28 of the lead 26 of the upper semiconductor die 10 being greater than the bend distance 28 of the lead 26 of the lower semiconductor die 10. In contrast, the left side of the stack 12 depicts the bend distance 28 of the lead 26 of the upper semiconductor die 10 being equal to the bend distance 28 of the lead 26 of the lower semiconductor die 10.

When the bend distances 28 of respective leads 26 of the upper and lower semiconductor dies 10 are equal to each other, the leads 26 of the upper semiconductor die 10 physically contact the top portion 32 of the leads 26 of the lower semiconductor die 10. In this regard, the footprint 40 of the semiconductor die stack 12 remains constant. The footprint 40 of the semiconductor die stack 12 is considered to be the area under the stack 12 including the area under the leads 26, as shown in FIG. 2.

When the bend distances 28 of the leads 26 of the upper semiconductor die 10 are greater than the bend distances 28 of the leads 26 of the lower semiconductor die 10, the leads 26 of the upper semiconductor die 10 physically contact the outside side portion 34 of the leads 26 of the lower semiconductor die 10, as shown in FIG. 3. In this regard, the foot print 40 of the semiconductor die stack 12 increases as more semiconductor dies 10 are stacked upon each other.

Alternatively, the leads 26 may be formed such that the leads 26 extend perpendicularly from a side surface 18, 20, 22, 24 and distal ends 36 of the leads 26 reside adjacent to the outside side portion 34, as shown on the left hand side of the stack 12 of FIG. 2. In this regard, the footprint 40 of the semiconductor die stack 12 remains constant as long as the leads 26 of the right side of the stack 12 were formed in a similar manner to the leads 26 of the left side of the stack 12.

The semiconductor die stack 12 may further comprise an adhesive 38 which is disposed between each pair of upper and lower semiconductor dies 10. In particular, the adhesive 38 physically contacts and adheres to the bottom surface 16 of the upper semiconductor die 10 and the top surface 14 of the lower semiconductor die 10. In this regard, the upper and lower semiconductor dies 10 are in substantially fixed relation to each other. In other words, upper and lower semiconductor dies 10 are in substantially fixed relationship to each other when respective leads 26 of such upper and lower semiconductor dies 10 are capable of being electrically connected through joining methods disclosed herein. The strength of the adhesive 38 needs to be sufficient such that the joining of respective leads 26 of the upper and lower semiconductor dies 10 may be accomplished through various means which are discussed in the description of the present invention or through other means known in the art.

The leads 26 of the upper semiconductor die 10 are electrically connected to respective ones of the leads 26 of the lower semiconductor die 10. By way of example and not limitation, the electrical connection may be made with conductive paste, conductive ink, solder, spot welding, laser welding, or combinations thereof. The Applicant has found however the laser welding is a preferred connection technique.

In relation to joining respective leads 26 with conductive paste or conductive ink, the leads 26 of the semiconductor dies 10 within the stack 12 are formed such that leads 26 of the upper semiconductor die 10 physically contact or are sufficiently close to respective ones of the leads 26 of the lower semiconductor dies 10 when stacked. Thereafter, the semiconductor dies 10 are vertically stacked upon each other. The physical relationship between the upper and lower semiconductor dies 10 are preserved throughout the process of electrically connecting respective leads 26 by utilizing the adhesive 38.

Conductive paste or conductive ink is subsequently placed on a portion of the lead 26 of the upper semiconductor die 10 and on a portion of the lead 26 of the lower semiconductor die 10. Preferably, the conductive paste or conductive ink 42 is placed on the distal end portion 36 of the lead 26 of the upper semiconductor die 10 so as to cover such distal end portion 36, as shown in FIG. 3. When conductive paste or conductive ink 42 is used, respective leads 26 of the upper and lower semiconductor dies 10 do not need to contact each other because the paste or ink 42 itself would create the electrical connection therebetween. In this regard, the leads 26 of the upper semiconductor dies 10 do not need to be pressed against, thereby deformed by, respective leads of the lower semiconductor die. Thereafter, the conductive paste or ink is cured. In this regard, the curing process reduces any residual stresses within the leads 26 themselves which were a result of deforming the leads 26 such that respective leads 26 of the upper and lower semiconductor dies 10 could be electrically connected. Additionally, the conductive paste or ink 42 behaves as a bridge such that respective leads 26 of the upper and lower semiconductor dies 10 do not need to be directly contacting each other to make an electrical connection therebetween; rather, the conductive paste or ink 42 is the intermediary to make the electrical connection therebetween. As such, there may not be any stresses associated with the direct physical contact between respective leads 26 of the upper and lower semiconductor dies 10.

Alternatively, instead of utilizing conductive pastes or inks, respective leads 26 of the upper and lower semiconductor dies 10 may be welded at localized spots on the leads 26 of the upper and lower semiconductor dies 10, namely at a portion where both respective leads 26 overlap (i.e., physically contact). The welding may be accomplished through spot welding or laser welding. Preferably, the electrical connection between respective leads 26 are made close to but not at the distal end portion 36 of the lead 26 of the upper semiconductor die 10, as shown in FIGS. 1 and 2. Additionally, the use of welding will deform and create residual stresses within the die stack.

As discussed above, leads 26 that extend out from opposing side surfaces 18, 20, 22, 24 of the semiconductor dies 10 have more uniform residual stresses compared to leads 26 that extend out from only two adjacent side surfaces (i.e., 18 and 19, or 20 and 22). In this regard, when respective leads 26 are welded together, the welds and the deformation of the leads 26 to physically attach the leads 26 create residual stresses. When the leads 26 extend out from opposing side surfaces (i.e., 18 and 22, or 20 and 24) of the semiconductor die 10, the stresses are generally balanced because the stresses from one side is equalized by the stresses from the opposing side. In contrast, when the leads 26 extend out from adjacent side surfaces, the stresses are not balanced because the opposing side does not have the equalizing stresses.

Additional modifications and improvements of the present invention may also be apparent to those of ordinary skill in the art. Thus, the particular combination of parts and steps described and illustrated herein is intended to represent only one embodiment of the present invention, and is not intended to serve as limitations of alternative devices and methods within the spirit and scope of the invention.

1) A semiconductor die stack comprising at least two semiconductor dies vertically stacked upon each other, each semiconductor die having leads, the leads of the upper semiconductor die(s) are directly connected to respective leads of the lower semiconductor die.

2) The semiconductor die stack of claim 1 wherein:
a) the semiconductor die defines opposed top and bottom surfaces and four side surfaces; and
b) the leads of each semiconductor die extend parallel to the opposed top and bottom surfaces from at least one of the side surfaces.

3) The semiconductor die stack of claim 2 wherein the leads of the bottom semiconductor die are bent downward.

4) The semiconductor die stack of claim 3 wherein a bend distance of the leads of each upper semiconductor die is progressively larger.

5) The semiconductor die stack of claim 4 wherein the bend distance of the leads of the upper semiconductor die is greater than the bend distance of the leads of the lower semiconductor die by the thickness of the leads.

6) The semiconductor die stack of claim 1 wherein the electrical connections between respective leads of the upper and lower semiconductor dies are made with conductive ink or conductive paste.

7) The semiconductor die stack of claim 1 wherein the electrical connections between respective leads of the upper and lower semiconductor dies are made through laser or arc welding.

8) The semiconductor die stack of claim 1 further comprising an adhesive disposed between each upper and lower semiconductor die.

9) The semiconductor die stack of claim 1 wherein the semiconductor die is a thin small outline package.
